(19) United States
(12) Patent Application Publication
(10) Pub. No.: US 2012/0307426 A1
(43) Pub. Date: Dec. 6, 2012

(54) INPUT/OUTPUT PORTS FIXTURE AND ELECTRONIC DEVICE USING THE SAME

(75) Inventor: WEI-JUN WANG, Shenzhen City (CN)

(73) Assignees: HON HAI PRECISION INDUSTRY CO., LTD., Tu-Cheng (TW); FU TAI HUA INDUSTRY (SHENZHEN) CO., LTD., ShenZhen City (CN)

(21) Appl. No.: 13/241,990

(22) Filed: Sep. 23, 2011

(30) Foreign Application Priority Data
May 31, 2011 (CN) 201110143703.6

(51) Int. Cl. H05K 7/00; H05K 7/14

(52) U.S. Cl. 361/679.01; 248/205.1

(57) ABSTRACT

An electronic device includes a housing, a fixing member fixed on the housing, an I/O ports fixture latched on the fixing member. The housing has one or more sidewalls, and each sidewall has an inner surface. The I/O ports fixture comprises a conducting sheet and a resilient bracket extending from one edge of the conducting sheet. The resilient bracket includes a plurality of elastic strips which are arranged apart. Each elastic strip has a protrusion resisting on the inner surface of the housing.

### BACKGROUND

1. Technical Field

The present disclosure relates generally to input/output ports (I/O ports) fixture and, particularly, to an electronic device using the input/output ports (I/O ports) fixture.

2. Description of Related Art

Generally, electrically conductive portions of an I/O ports fixture usually use bar-type elastic strips forming a plurality of protrusions on a surface thereof for electrically contacting corresponding components of the electronic device.

However, to function properly and hold up over time, both the bar-type elastic strip and the corresponding contact surfaces of the components need to be very straight, and any variance can result in poor performance

Therefore, there is room for improvement within the art.

### BRIEF DESCRIPTION OF THE DRAWINGS

The elements in the drawings are not necessarily drawn to scale, the emphasis instead placed upon clearly illustrating the principles of the present disclosure. Moreover, in the drawings, like reference numerals designate corresponding parts throughout the several views.

FIG. 1 is a partial, isometric view of an embodiment of an electronic device including a housing, an I/O ports fixture, a fixing member, and a supporting member.

FIG. 2 is an exploded, isometric view of the I/O ports fixture shown in FIG. 1.

FIG. 3 is an enlarged, isometric view of the I/O ports fixture shown in FIG. 2.

FIG. 4 is an isometric view of the I/O ports fixture assembled with the fixing member and the supporting member of FIG. 1.

### DETAILED DESCRIPTION

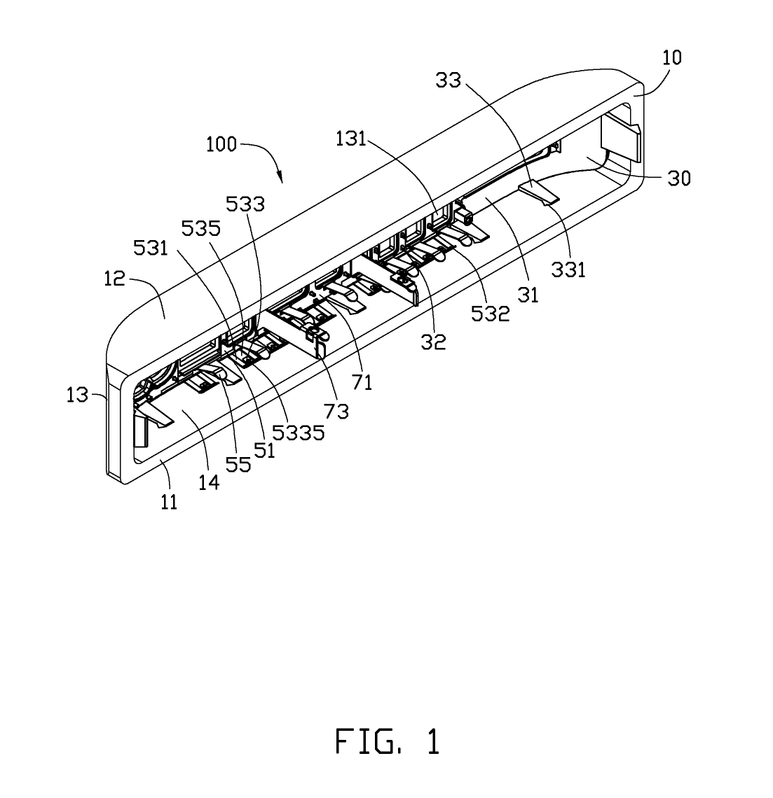

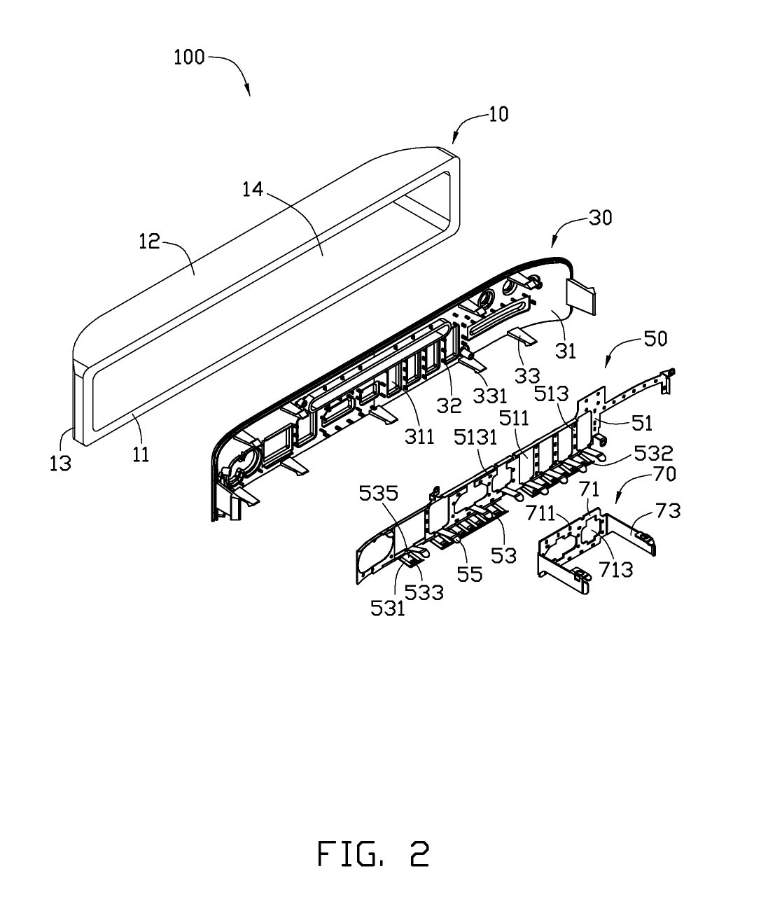

Referring to FIGS. 1 and 2, an embodiment of an electronic device 100 includes a housing 10, a fixing member 30, an input/output (I/O) ports fixture 50, and a supporting member 70. The fixing member 30 is mounted in the housing 10. The I/O ports fixture 50 is latched on the fixing member 30. The supporting member 70 is latched on the I/O ports fixture 50. The device 100 can be a mobile phone, a personal digital assistant (PDA), a computer etc. The electronic device 100 includes various electronic components to perform corresponding functions and features; however for simplicity, in the following embodiment, only the I/O ports fixture 50 and related components are described. The supporting member 70 is contacted with the electronic components and supporting the input/output (I/O) ports fixture 50. In the illustrated embodiment, the electronic device 100 is a computer with a plurality of I/O ports.

The housing 10 includes a first sidewall 11, a second sidewall 12 opposite to the first sidewall 11, and a mounting wall 13 interconnecting the first sidewall 11 with the second sidewall 12. The first sidewall 11, the second sidewall 12, and the mounting wall 13 cooperatively form a receiving cavity 14. In the illustrated embodiment, the first sidewall 11 is parallel to the second sidewall 12. Both the first sidewall 11 and the second sidewall 12 are perpendicular to the mounting wall 13. The mounting wall 13 is an arcuate sidewall defining a plurality of first through holes 131. The housing 10 can be made of metallic materials or nonmetallic materials coated with electrically conductive material. In the illustrated embodiment, the housing 10 is metallic.

The fixing member 30 is made of insulating materials, and includes a plate body 31, a plurality of fixing portions 32, and a plurality of resisting portions 33. In the illustrated embodiment, the body 31 is an arcuate wall curved to match the mounting wall 13. The fixing portions 32 are formed at a surface of the plate body 31 away from the mounting wall 13. In the illustrated embodiment, the fixing portions 32 are a plurality of fixing pins. The resisting portions 33 extend outward from an edge of the surface of the plate body 31 away from the mounting wall 13. A plurality of second through holes 311 are defined in the plate body 31 corresponding to the first through holes 131. The fixing portions 32 are spaced apart and arranged surrounding the second through holes 311. The resisting portions 33 are a plurality of elongated portions. A hook 331 is formed on a distal end of each resisting portion 33 for latching in a corresponding groove (not shown) defined in the first sidewall 11 or the second sidewall 12 to fix the fixing member 30 to the housing 10. In the illustrated embodiment, the fixing member 30 is made of a plastic material.

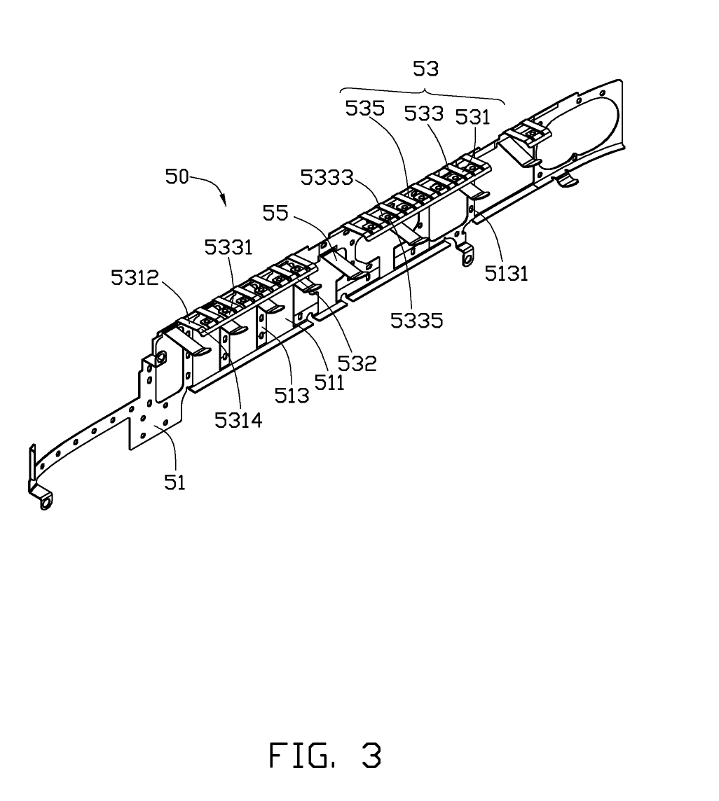

Referring to FIG. 3, in the illustrated embodiment, the fixture 50 is manufactured by punching, and includes a conducting sheet 51, two resilient brackets 53, and a plurality of contacting ends 55. The conducting ends 51 forms a supporting surface 513 away from the mounting wall 13 and defines a plurality of third through holes 511 in the supporting surface 513. The third through holes 511 correspond to the second through holes 311. The supporting surface 513 further defines a plurality of first inserting holes 5131 for receiving the fixing portions 32, respectively. The two resilient brackets 53 extend from one edge of the conducting sheet 51. The two resilient brackets 53 are spaced apart. In an alternative embodiment, one or more resilient brackets 53 can be disposed on and extended from the conducting sheet 51. The contacting ends 55 extend from one edge of the conducting sheet 51 in a same direction as the resilient brackets 53.

Each resilient bracket 53 is substantially rectangular, including a plurality of supporting pieces 531, an elastic portion 532, and a plurality of elastic strips 533. The supporting pieces 531 extend from one edge of the conducting sheet 51. The elastic portion 532 is strip-shaped, and connects the ends of the supporting pieces 531 together. Each of the elastic strips 533 extends from the elastic portion 532 toward the conducting sheet 51, and are disposed between the two adjacent supporting pieces 531. The elastic strips 533 are spaced apart. The two adjacent supporting pieces 531, the elastic strip 533 between two supporting pieces 531 and the elastic portions 532 cooperatively define an opening hole 535. In the illustrated embodiment, the supporting pieces 531 are parallel to each other, and gaps are defined between each elastic strip 533 and two adjacent supporting pieces 531.

Each of the supporting pieces 531 includes a supporting surface 5312 and a protrusion portion 5314. The supporting surface 5312 extends from the conducting sheet 51 outward of the conducting sheet 51. The protrusion portion 5314 interconnects the supporting surfaces 5312 with the elastic portion 532. The supporting surfaces 5312 of the supporting pieces 531 are substantially coplanar. Each of the elastic strips 533 includes a protruding portion 5331 and an extending portion 5333. The protruding portion 5331 is protruded from an edge of the elastic portion 532 adjacent to the supporting pieces 531 toward the conducting sheet 51. The extending portion 5333 extends from a distal end of the protruding portion 5331 away from the elastic portion 532. The protruding portions 5331 of the elastic strips 533 are higher than the elastic portion 532 and maximal heights of the protruding portions 5331 are substantially the same. Thus, the extending portions 5333 of the elastic strips 533 are substantially coplanar. Each of the elastic strips 533 further includes a protrusion 5335 formed on a top surface of each extending portion 5333 for resisting an inner surface of the first sidewall 11 of the housing 10. The protrusions 5335 are semispherical. In the illustrated embodiment, the protrusions 5335 are integrated with the extending portions 5333. In this embodiment the input/output (I/O) ports fixture 50 is made of metallic materials and formed by punching, however, in other embodiment the I/O ports fixture 50 may be made of nonmetallic materials coated with electrically conductive material, and formed appropriately such as by injection molding.

The supporting member 70 is made of electrically conductive material. The supporting member 70 includes a latching body 71 and a plurality of supporting stands 73. A plurality of second inserting holes 711 are defined in the latching body 71 corresponding to the first inserting holes 5131 of the supporting surface 513 for being latched with the fixing portions 32. A plurality of fourth through holes 713 are defined in the latching body 71 corresponding to the third through holes 511 of the conducting sheet 51. The supporting stands 73 substantially perpendicularly extend from two opposite edges of the latching body 71. The supporting stands 73 are configured for contacting with the electronic components (not shown) fixed in the housing 10.

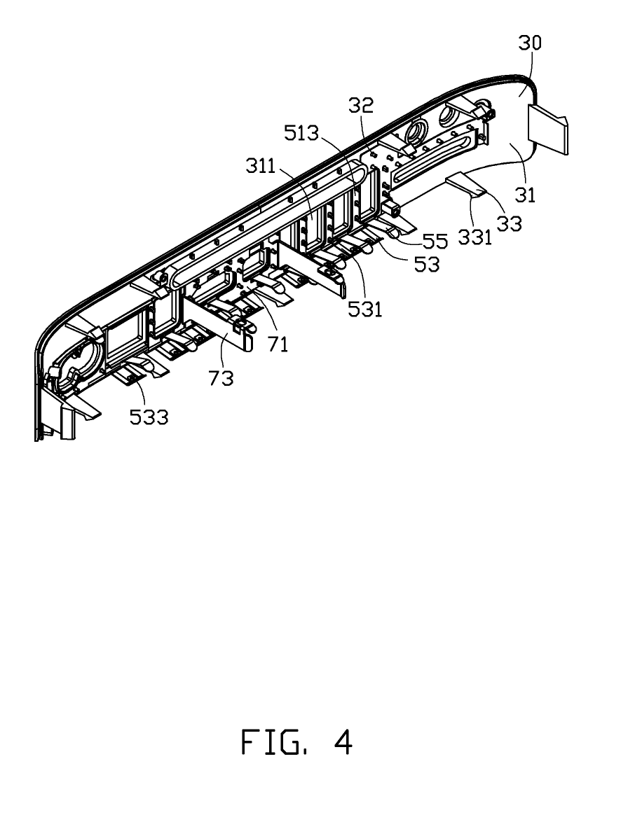

Referring to FIG. 4, when the electronic device 100 is assembled. Firstly, the conducting sheet 51 is pressed to the plate body 31 to allow the fixing portions 32 to extend through the corresponding first inserting holes 5131. At the same time, the third through holes 511 are communicated with the second through holes 311 of the fixing member 30. Secondly, the supporting member 70 is provided to support the I/O ports fixture 50 at a side of the I/O ports fixture 50 away from the housing 10. At this time, the second inserting holes 711 of the latching body 71 are arranged to overlap with the first inserting holes 5131 of the I/O ports fixture 50 and some of the fixing portions 32 pass through the correspondingly second inserting holes 711 of the latching body 71. At this time, the fixing member 30, the I/O ports fixture 50 and the supporting member 70 are assembled together. Finally, the fixing member 30 assembled with the I/O ports fixture 50 and the supporting member 70 is provided to engage in the receiving cavity 14 of the housing 10. The resisting portions 33 are resisted on the inner surface of the first sidewall 11 and the inner surface of the second sidewall 12, respectively. The hooks 331 formed on the distal end of the resisting portion 33 are latched in the latching grooves of the inner surface of the first sidewall 11 and the inner surface of the second sidewall 12, to fix the fixing member 30 to the housing 10.

In use, in the illustrated embodiment, an USB (not shown) is provided to insert to one I/O port through the first through hole 131. The protrusions 5335 are resisted on the inner surface of the first sidewall 11, such that the elastic strips 533 are deformed by the pressure of the first sidewall 11. The elastic strips 533 are deformed individually because of being spaced apart. Thus, each of the protrusions 5335 can contact the first sidewall 11 tightly. Therefore, an electrically conductive capability of the I/O ports fixture 50 with the housing 10 is enhanced.

The elastic strips 533 are pressed against and deformed by the inner surface of the sidewall 11 without affecting other elastic strips 533. In applications where the first sidewall 11 or the resilient bracket 53 are formed with a plurality of curves or bends, the protruding portions 5331 ensure adequate contact against the first sidewall 11 for good conductivity. In addition, because the opening holes 535 are defined between the elastic strips 533 and the supporting pieces 531, and the gaps are defined between the protruding portions 5331 of the elastic strips 533 and the supporting pieces 531, the elastic strips 533 are deformed without being affected by the supporting pieces 531 when pressed by the first sidewall 11. Furthermore, with the relatively greater elasticity of the elastic strips 533, friction between the protrusions 5335 and the first sidewall 11 is minimized, thereby reducing wear and tear to the housing 10.

It should be noted that the protrusions 5335 can also resist on the other portion of the housing 10, for example, the inner surface of the second sidewall 12. In addition, supporting member 70 can also be omitted, or formed on the I/O ports fixture 50 directly, or configured in other ways to ensure that the I/O ports fixture 50 are electrically connected with the electronic component. The elastic strips 533 can also extend from the conducting sheet 51 in a spaced apart configuration.

It is believed that the present embodiments and their advantages will be understood from the foregoing description, and it will be apparent that various changes may be made thereto without departing from the spirit and scope of the disclosure or sacrificing all of its material advantages.

What is claimed is:

1. An input/output ports fixture for being assembled in a housing of an electronic device, the housing having one or more sidewalls, comprising:
a conducting sheet; and
at least one resilient bracket extending from one edge of the conducting sheet;
wherein the at least one resilient bracket comprises a plurality of elastic strips, the elastic strips are spaced apart, and each of the elastic strips forms a protrusion on a top surface thereof to resisting an inner surface of the sidewalls of the housing.

2. The input/output ports fixture of claim 1, wherein the at least one resilient bracket comprises a plurality of supporting pieces extending from one edge of the conducting sheet and an elastic portion connecting the distal ends of the supporting pieces, the supporting pieces are spaced apart; and each of the elastic strips extends from the elastic portion towards the conducting sheet, and are disposed between the two adjacent supporting pieces.

3. The input/output ports fixture of claim 2, wherein the two adjacent supporting pieces, the elastic strip between two supporting pieces and the elastic portions cooperatively form an opening hole.

4. The input/output ports fixture of claim 2, wherein a plurality of gaps are defined between each elastic strip and two supporting pieces adjacent to the elastic strip.

5. The input/output ports fixture of claim 2, wherein each of the elastic strip comprises a protruding portion protruding from one edge of the elastic portion and an extending portion extending from a distal end of the protruding portion away from the elastic portion; the protrusions are formed on the top surfaces of the extending portions.

6. The input/output ports fixture of claim 5, wherein the maximal heights of the protruding portions of the elastic strips are the same, and higher than the heights of the supporting surfaces; the extending portions of the elastic strips are substantially coplanar.

7. The input/output ports fixture of claim 5, wherein the protruding portions of the elastic strips are higher than the elastic portion.

8. An electronic device, comprising:
a housing;
a fixing member fixed in the housing;
an input/output ports fixture latched on the fixing member;
wherein the housing has one or more sidewalls, and an inner surface on each sidewall;
the input/output ports fixture comprises a conducting sheet and a resilient bracket extending from one edge of the conducting sheet; the resilient bracket comprises a plurality of elastic strips, the elastic strips are arranged apart, and each of the elastic strips forms a protrusion on a top surface thereof to resisting an inner surface of the sidewall of the housing.

9. The electronic device of claim 9, wherein the at least one resilient bracket comprises a plurality of supporting pieces extending from one edge of the conducting sheet and an elastic portion connecting the distal ends of the supporting pieces, the supporting pieces are spaced apart; and each of the elastic strips extends from the elastic portion towards the conducting sheet, and are disposed between the two adjacent supporting pieces.

10. The electronic device of claim 9, wherein the two adjacent supporting pieces, each of the elastic strip between two supporting pieces and the elastic portions cooperatively form an opening hole.

11. The electronic device of claim 9, wherein a plurality of gaps are defined between each elastic strip and two supporting pieces adjacent to the elastic strip.

12. The electronic device of claim 9, wherein each of the elastic strip comprises a protruding portion protruding from one edge of the elastic portion and an extending portion extending from a distal end of the protruding portion away from the elastic portion; the protrusions are formed on the top surfaces of the extending portions.

13. The electronic device of claim 12, wherein the maximal heights of the protruding portions of the elastic strips are the same, and are higher than the heights of the supporting surfaces; the extending portions of the elastic strips are substantially coplanar.

14. The electronic device of claim 12, wherein the protruding portions of the elastic strips are higher than the elastic portion.

15. The electronic device of claim 8, wherein the electronic device also comprises a plurality of electronic components, and a supporting member latching on the conducting sheet and resisting on the electronic components.

16. The electronic device of claim 15, wherein the input/output ports fixture further comprises a plurality of contacting ends extending from one edge of the conducting sheet; the contacting ends contact with the electronic components.

17. The electronic device of claim 8, wherein the fixing member comprises a plurality of fixing portions fixing the input/output ports fixture and a plurality of resisting portions resisted on the inner surface of the sidewall of the housing.

18. The electronic device of claim 17, wherein a hook is formed on a distal end of each resisting portion for latching in a corresponding groove defined in the housing.
